(19) United States
(12) Patent Application Publication
(10) Pub. No.: US 2023/0335684 A1
(43) Pub. Date: Oct. 19, 2023

(54) WHITE LIGHT LED CHIP PACKAGED IN INORGANIC MATERIAL, DEVICE, PREPARATION METHOD THEREFOR, AND APPLICATION THEREOF

(71) Applicant: FUJIAN CAS-CERAMIC OPTOELECTRONICS TECHNOLOGY CO., LTD, Fuzhou, Fujian (CN)

(72) Inventors: Xiuqiang ZHANG, Fuzhou, Fujian (CN); Maochun HONG, Fuzhou, Fujian (CN); Shujiang ZHANG, Fuzhou, Fujian (CN); Youfu ZHOU, Fuzhou, Fujian (CN); Xiao LIN, Fuzhou, Fujian (CN)

(21) Appl. No.: 18/042,684

(22) PCT Filed: Apr. 16, 2021
(86) PCT No.: PCT/CN2021/087787

§ 371 Date: Feb. 23, 2023

(30) Foreign Application Priority Data
Oct. 13, 2020 (CN) 202011092334.8
Mar. 3, 2021 (CN) 202110235139.4

(51) Int. Cl. H01L 33/50; H01L 25/075; H01L 33/64

(52) U.S. Cl. CPC H01L 33/502; H01L 25/0753; H01L 33/641; H01L 2933/0041

(57) ABSTRACT

A white light LED chip packaged in inorganic material, a device, a preparation method therefor, and an application thereof are provided. The white light LED chip includes an LED chip wafer, an inorganic material packaging layer and a single crystal substrate. The LED chip wafer has at least one flip or vertical LED chip. The inorganic material packaging layer packages the LED chip wafer. The inorganic material packaging layer has a fluorescent transparent ceramic piece or a fluorescent crystal piece.

The present application claims priority to the following two prior applications of the applicant: Patent Application No. 202011092334.8 filed with China National Intellectual Property Administration on Oct. 13, 2020 and entitled “WHITE LED CHIP PACKAGED IN INORGANIC MATERIAL, DEVICE, PREPARATION METHOD THEREFOR AND APPLICATION THEREOF”; and Patent Application No. 202110235139.4 filed with China National Intellectual Property Administration on Mar. 3, 2021 and entitled “WHITE LED CHIP PACKAGED IN INORGANIC MATERIAL, DEVICE, PREPARATION METHOD THEREFOR AND APPLICATION THEREOF”, which are incorporated herein by reference in their entirety.

### TECHNICAL FIELD

The present disclosure belongs to the field of semiconductor illumination, and specifically to a white LED chip packaged in an inorganic material, a device, a preparation method therefor and application thereof.

### BACKGROUND

As a fourth generation light source, LED has excellent performance including high luminous efficiency, lower power consumption, environmental friendliness, longer lifetime and the like compared with the conventional light source, and LED has been widely applied in the fields of outdoor lighting, venue lighting, indoor lighting and the like. In the conventional LED light source, Y₃Al₅O₁₂:Ce (YAG:Ce) fluorescent powder is packaged in organic substances such as epoxy resin or silica gel, due to the poor heat dissipation performance of these organic packaging materials, the heat generated in the operation process of an LED chip is not easy to dissipate, leading to a rise in the temperature of the light source, after the LED light source operates for a long time, these organic packaging materials will become aged and decomposed, causing problems such as light attenuation, color shift, shortened lifetime and the like. A YAG:Ce fluorescent transparent ceramic has higher thermal conductivity and thermal stability, and the use thereof as an LED packaging material can effectively solve the problems including light attenuation, color shift, shortened lifetime and the like caused by the poor heat dissipation performance of organic packaging materials.

As a connecting link in the LED industry chain, LED packaging plays a key role in the entire industry chain. For packaging, the key is how to extract as much light emitted by the chip as possible within a limited cost range, and meanwhile, the packaging thermal resistance is reduced, and the reliability is improved. In the process of LED packaging, packaging materials and packaging modes are the main influencing factors. With the development of LED products toward high performance such as high light luminous efficiency, high power density and high reliability, higher and higher requirements are put forward for packaging. On the one hand, the packaging of LED products must meet the requirements of high enough light extraction efficiency and luminous flux while taking into account the light-emitting angle, uniformity of light color and the like; on the other hand, the packaging must meet the heat dissipation requirements of the chip. Therefore, different materials such as chips, fluorescent materials and substrates, and corresponding packaging modes need to be continuously developed and innovated to improve the heat dissipation capability and the light-emitting efficiency of LED products.

With the rapid development of LED technology, the packaging form of LED products has also developed from single-chip packaging to multi-chip packaging, and the packaging structure has developed from Lamp packaging to SMD packaging to COB packaging and other technologies. Among them, the COB (chip on Board) packaging structure is formed by directly pasting a plurality of LED chips on a mirror-surface metal substrate without processes of supporting, electroplating, reflow soldering and the like, however, chips must be connected with each other by a wire, which difficult to ensure that multiple fluorescent powder dispensing is completely consistent. The COB packaging structure has the advantages of compact structure, simpler process and the like, but has the defects of possibility of wire breakage, poor light and color consistency and the like.

Patent literature 201510900839.5 discloses a wafer-level packaged flip-chip LED, which comprises an LED chip wafer/array, a conductive substrate and a fluorescent powder transparent substrate; a growth substrate of the LED chip is peeled off by adopting a chemical method, and the fluorescent powder transparent substrate is bonded to a light-emitting surface of the LED chip described above, which improves the light-emitting efficiency of the flip-chip LED, avoids cumbersome wiring and other designs, and reduces packaging costs. In this patent, the substrate needs to be peeled off, meanwhile, the fluorescent powder transparent substrate adopts SiO₂-based glass and an organic transparent material, and organic substances such as silica gel are still used for being bonded to the light-emitting surface of the chip, which all cause complex process and poor heat resistance of a bonding interface.

Patent literature 201410299430.8 discloses a GaN-based LED epitaxial structure and a manufacturing method therefor, wherein the GaN-based LED epitaxial structure is epitaxially grown on a substrate containing a photoluminescent fluorescent material, and the substrate is Re₃Al₅O₁₂ ceramic or single crystal, or single crystal is thermally bonded to Re₃Al₅O₁₂ ceramic, so that the direct white light emission can be realized, and the preparation process of the white LED light source is simplified. In this patent, a ceramic substrate is used for growing the LED epitaxial structure; since the Re₃Al₅O₁₂ ceramic is in a polycrystalline structure, which will cause the LED chip grown on the ceramic substrate has many defects and cannot be used in practice; the mismatch between Re₃Al₅O₁₂ polycrystalline substrate and GaN material is large, so there is no report of practical application; the Al₂O₃ single crystal and the Re₃Al₅O₁₂ ceramic sheet are thermally bonded, and due to the difference in thermal expansion coefficient between the two, the heating and cooling in the thermal bonding process will easily lead to thermal bonding failure, which is not operated in practice.

Patent literature 201810843269.4 discloses a flip-chip LED chip, wherein the chip uses a fluorescent ceramic substrate distributed with fluorescent particles as a substrate, an LED epitaxial structure such as an N-type epitaxial layer is grown on a first surface of the substrate, and a flip-chip LED chip is formed, thereby avoiding the use of fluorescent glue, and improving the heat resistance of the chip and the reliability of LED devices. However, there is also a problem that the chips grown on the ceramic substrate cannot be used in practice due to a plurality of defects.

### SUMMARY

Aiming at the above-mentioned defects in the prior art, the present disclosure provides a white LED chip packaged in an inorganic material, a device, a preparation method therefor and application thereof.

The present disclosure provides a white LED chip, which comprises: an LED chip wafer and an inorganic material packaging layer; the white LED chip further comprises a single crystal substrate;

the LED chip wafer at least comprises an LED chip with a flip-chip or vertical structure;

the inorganic material packaging layer is configured to package the LED chip wafer, the inorganic material packaging layer comprises a fluorescent transparent ceramic sheet or a fluorescent crystal sheet.

According to an embodiment of the present disclosure, the single crystal substrate is a sapphire (aluminum oxide) substrate, a silicon carbide substrate or a gallium nitride substrate.

According to an embodiment of the present disclosure, the inorganic material packaging layer comprises a fluorescent transparent ceramic layer and a bonding layer, or comprises a fluorescent crystal layer and a bonding layer. For example, a material of the fluorescent transparent ceramic layer includes but is not limited to a fluorescent transparent ceramic based on YAG and the like, preferably a YAG-based fluorescent transparent ceramic; for example, a material of the fluorescent crystal layer includes but is not limited to a fluorescent crystal based on YAG and the like (the fluorescent crystal is, for example, a fluorescent single crystal, a fluorescent polycrystalline, or a fluorescent quasicrystal), preferably a YAG-based fluorescent crystal; for example, the bonding layer includes but is not limited to at least one of a metal elementary substance layer, a gluing layer, a sintered interface layer, a ceramic bonding layer and a buffer layer.

Preferably, the fluorescent transparent ceramic layer or the fluorescent crystal layer is a light-emitting surface of the inorganic material packaging layer.

Preferably, in the white LED chip described above, a material of the ceramic bonding layer is the same as or different from, preferably the same as, a single crystal material of the single crystal substrate. For example, the material of the ceramic bonding layer is selected from aluminum oxide, silicon carbide or gallium nitride, preferably aluminum oxide.

Preferably, the YAG-based fluorescent transparent ceramic includes but is not limited to yttrium aluminum garnet-type fluorescent transparent ceramics such as YAG:Ce, YAG:Ce, Mn and LuAG:Ce.

Preferably, the YAG-based fluorescent crystal includes but is not limited to yttrium aluminum garnet-type fluorescent crystals such as YAG:Ce and LuAG:Ce.

According to an embodiment of the present disclosure, the inorganic material packaging layer is composed of a fluorescent transparent ceramic layer and a bonding layer, or is composed of a fluorescent crystal layer and a bonding layer. Preferably, a non-light-emitting surface of the fluorescent transparent ceramic layer is bonded to the bonding layer. Preferably, a non-light-emitting surface of the fluorescent crystal layer is bonded to the bonding layer.

For example, the bonding layer is a metal elementary substance layer, that is, a metal elementary substance layer is arranged between the non-light-emitting surface of the fluorescent transparent ceramic layer and the LED chip wafer, and the fluorescent transparent ceramic layer is bonded to the LED chip wafer through metal bonding. For example, the bonding layer is a metal elementary substance layer, that is, a metal elementary substance layer is arranged between the non-light-emitting surface of the fluorescent crystal layer and the LED chip wafer, and the fluorescent crystal layer is bonded to the LED chip wafer through metal bonding. The metal elementary substance includes but is not limited to at least one of Au, Ag, In, Sn, Pb and the like.

For example, the metal elementary substance layer has a thickness of no more than 0.1 mm, for example no more than 0.08 mm, and another example no more than 0.05 mm.

For example, the bonding layer is a gluing layer, that is, a gluing layer is arranged between the non-light-emitting surface of the fluorescent transparent ceramic layer and the LED chip wafer, and the fluorescent transparent ceramic layer is bonded to the LED chip wafer through gluing. For example, the bonding layer is a gluing layer, that is, a gluing layer is arranged between the non-light-emitting surface of the fluorescent crystal layer and the LED chip wafer, and the fluorescent crystal layer is bonded to the LED chip wafer through gluing. The glue in the gluing layer can be epoxy resin or silica gel. It should be noted that the amount of glue is small, and the gluing layer has a thickness of no more than 10 for example no more than 8 and another example no more than 5 μm.

For example, the bonding layer is a sintered interface layer, that is, a sintered interface layer is arranged between the non-light-emitting surface of the fluorescent transparent ceramic layer and the LED chip wafer, and the sintered interface layer is formed by heating, so that thermal bonding between the fluorescent transparent ceramic layer and the LED chip wafer is realized. The sintered interface layer is formed by performing sintering between the fluorescent transparent ceramic layer and the LED chip wafer at a certain temperature, the main component of the sintered interface layer is an inorganic compound, the inorganic compound contains elements such as Al, Y, Si, Ga, O and N, and at least one of covalent bonds including but not limited to Al—O, Y—O, Si—O, Ga—N and Al—N exists among the elements. For example, the sintered interface layer has a thickness of no more than 10 for example no more than 8 and another example no more than 5 μm.

For example, the bonding layer is a sintered interface layer, that is, a sintered interface layer is arranged between the non-light-emitting surface of the fluorescent crystal layer and the LED chip wafer, and the sintered interface layer is formed by heating, so that thermal bonding between the fluorescent crystal layer and the LED chip wafer is realized. The sintered interface layer is formed by performing sintering between the fluorescent crystal layer and the LED chip wafer at a certain temperature, the main component of the sintered interface layer is an inorganic compound, the inorganic compound contains at least one of elements such as Al, Y, Si, Ga, O and N, and at least one of covalent bonds including but not limited to Al—O, Y—O, Si—O, Ga—N and Al—N exists among the elements. For example, the sintered interface layer has a thickness of no more than 10 μm, for example no more than 8 μm, and another example no more than 5 μm.

For example, the bonding layer comprises a ceramic bonding layer and a sintered interface layer, that is, a ceramic bonding layer and a sintered interface layer are arranged between the non-light-emitting surface of the fluorescent transparent ceramic layer and the LED chip wafer, and a material of the ceramic bonding layer is the same as a single crystal material of the single crystal substrate in the LED chip wafer; covalent bonds among the fluorescent transparent ceramic layer, the ceramic bonding layer and the single crystal substrate of the LED chip wafer are generated by heating to realize bonding. For example, the ceramic bonding layer has a thickness of 0.2 to 2.0 mm, for example 0.4 to 1.6 mm, and another example 0.6 to 1.2 mm.

For example, the bonding layer comprises a ceramic bonding layer and a sintered interface layer, that is, a ceramic bonding layer and a sintered interface layer are arranged between the non-light-emitting surface of the fluorescent crystal layer and the LED chip wafer, and a material of the ceramic bonding layer is the same as a single crystal material of the single crystal substrate in the LED chip wafer; covalent bonds among the fluorescent crystal layer, the ceramic bonding layer and the single crystal substrate of the LED chip wafer are generated by heating to realize bonding. For example, the ceramic bonding layer has a thickness of 0.2 to 2.0 mm, for example 0.4 to 1.6 mm, and another example 0.6 to 1.2 mm.

For example, the bonding layer is a buffer layer, that is, a buffer layer is arranged between the non-light-emitting surface of the fluorescent transparent ceramic layer and the LED chip wafer (for example, the buffer layer is grown on the non-light-emitting surface by chemical vapor deposition (CVD) and other modes), and then an LED epitaxial structure is further grown on the buffer layer, so as to manufacture a wafer with a plurality of LED chips and in a flip-chip or vertical structure. The buffer layer is a buffer layer that is deposited and grown on the non-light-emitting surface of the fluorescent transparent ceramic layer and is compatible with the epitaxial structure, preferably including but not limited to at least one of materials such as SiC, Si, SiO₂, In₂O₃, AlN, and AlₓGa_{y}N. AlₓGa_{y}N is a gradient material (X+Y=1.0, X and Y vary between 0.00 and 1.00), for example, it transitions from AlN, Al_{0.9}Ga_{0.1}N, Al_{0.5}Ga_{0.5}N, Al_{0.1}Ga_{0.9}N to GaN. For example, the buffer layer has a thickness of no more than 10 μm, for example no more than 8 μm, and another example no more than 5 μm.

For example, the bonding layer is a buffer layer, that is, a buffer layer is arranged between the non-light-emitting surface of the fluorescent crystal layer and the LED chip wafer (for example, the buffer layer is grown on the non-light-emitting surface by chemical vapor deposition (CVD) and other modes), and then an LED epitaxial structure is further grown on the buffer layer, so as to manufacture a wafer with a plurality of LED chips and in a flip-chip or vertical structure. The buffer layer is a buffer layer that is deposited and grown on the non-light-emitting surface of the fluorescent crystal layer and is compatible with the epitaxial structure, preferably including but not limited to at least one of materials such as SiC, Si, SiO₂, In₂O₃, AlN, and AlₓGa_{y}N. AlₓGa_{y}N is a gradient material (X+Y=1.0, X and Y vary between 0.00 and 1.00), for example, it transitions from AlN, Al_{0.9}Ga_{0.1}N, Al_{0.5}Ga_{0.5}N, Al_{0.1}Ga_{0.9}N to GaN. For example, the buffer layer has a thickness of no more than 10 μm, for example no more than 8 μm, and another example no more than 5 μm.

According to an embodiment of the present disclosure, the LED chip comprises an N-type epitaxial layer, an emissive layer and a P-type epitaxial layer.

According to an embodiment of the present disclosure, the LED chip is arranged on a non-light-emitting surface of the single crystal substrate or a non-light-emitting surface of the inorganic material packaging layer.

According to an embodiment of the present disclosure, the LED chip wafer may comprise one, two, three or more LED chips with flip-chip or vertical structures.

According to an embodiment of the present disclosure, the fluorescent transparent ceramic has a light transmittance of 5%-85%; for example, 30%-85%; preferably, the fluorescent transparent ceramic has a light transmittance of 75%-85%.

According to an exemplary embodiment of the present disclosure, the white LED chip comprises: an LED chip wafer, an inorganic material packaging layer and a single crystal substrate;

the LED chip wafer comprises at least one LED chip with a flip-chip or vertical structure;

the inorganic material packaging layer is configured to package the LED chip wafer and composed of a fluorescent transparent ceramic layer and a bonding layer, a material of the fluorescent transparent ceramic layer includes but is not limited to a fluorescent transparent ceramic based on YAG and the like, and the bonding layer includes but is not limited to at least one of a metal elementary substance layer, a sintered interface layer, a gluing layer, a ceramic bonding layer and a buffer layer;
the single crystal substrate is a sapphire (aluminum oxide) substrate, a silicon carbide substrate or a gallium nitride substrate;
a material of the ceramic bonding layer is the same as a single crystal material in the single crystal substrate.

According to an exemplary embodiment of the present disclosure, the white LED chip comprises: an LED chip wafer, an inorganic material packaging layer and a single crystal substrate;
the LED chip wafer comprises at least one LED chip with a flip-chip or vertical structure;
the inorganic material packaging layer is configured to package the LED chip wafer and composed of a fluorescent crystal layer and a bonding layer, a material of the fluorescent crystal layer includes but is not limited to a fluorescent crystal layer based on YAG and the like, and the bonding layer includes but is not limited to at least one of a metal elementary substance layer, a sintered interface layer, a gluing layer, a ceramic bonding layer and a buffer layer;
the single crystal substrate is a sapphire (aluminum oxide) substrate, a silicon carbide substrate or a gallium nitride substrate;
a material of the ceramic bonding layer is the same as a single crystal material in the single crystal substrate.

According to an exemplary embodiment of the present disclosure, the white LED chip comprises: an LED chip wafer and an inorganic material packaging layer;
the LED chip wafer comprises at least one LED chip with a flip-chip or vertical structure;
the inorganic material packaging layer is configured to package the LED chip wafer and composed of a fluorescent transparent ceramic layer and a bonding layer, a material of the fluorescent transparent ceramic layer includes but is not limited to a fluorescent transparent ceramic based on YAG and the like, and the bonding layer includes but is not limited to at least one of a metal elementary substance layer, a sintered interface layer, a gluing layer and a buffer layer;
preferably, at least one of a metal elementary substance layer, a sintered interface layer, a gluing layer and a buffer layer is arranged between a non-light-emitting surface of the fluorescent transparent ceramic layer and the LED chip wafer, so that the fluorescent transparent ceramic sheet is bonded to the LED chip wafer.

According to an exemplary embodiment of the present disclosure, the white LED chip comprises: an LED chip wafer and an inorganic material packaging layer;
the LED chip wafer comprises at least one LED chip with a flip-chip or vertical structure;
the inorganic material packaging layer is configured to package the LED chip wafer and composed of a fluorescent crystal layer and a bonding layer, a material of the fluorescent crystal layer includes but is not limited to a fluorescent crystal layer based on YAG and the like, and the bonding layer includes but is not limited to at least one of a metal elementary substance layer, a sintered interface layer, a gluing layer and a buffer layer;
preferably, at least one of a metal elementary substance layer, a sintered interface layer, a gluing layer and a buffer layer is arranged between a non-light-emitting surface of the fluorescent crystal layer and the LED chip wafer, so that the fluorescent crystal layer is bonded to the LED chip wafer.

The present disclosure further provides a preparation method for the white LED chip described above, which comprises the following steps: packaging the LED chip wafer by using the inorganic material packaging layer comprising the fluorescent transparent ceramic layer or the fluorescent crystal layer;
the inorganic material packaging layer, the fluorescent transparent ceramic layer, the fluorescent crystal layer and the LED chip wafer have the meanings as described above.

According to an embodiment of the present disclosure, the preparation method for the white LED chip described above comprises the following steps:
(1) enabling an epitaxial structure to grow based on the single crystal substrate, wherein the epitaxial structure comprises: an N-type epitaxial layer, an emissive layer and a P-type epitaxial layer;
(2) manufacturing the LED chip wafer comprising at least one LED chip with a flip-chip or vertical structure on the epitaxial structure;
(3) packaging the LED chip wafer by using the fluorescent transparent ceramic layer and the bonding layer, wherein the fluorescent transparent ceramic layer is used as a light-emitting surface; or packaging the LED chip wafer by using the fluorescent crystal layer and the bonding layer, wherein the fluorescent crystal layer is used as a light-emitting surface, and obtaining the white LED chip.

According to an embodiment of the present disclosure, the fluorescent transparent ceramic layer, the fluorescent crystal layer and the single crystal substrate have the meanings as described above.

According to an embodiment of the present disclosure, in step (3), the bonding layer has the meaning as described above.

According to an embodiment of the present disclosure, the packaging is realized by bonding (for example metal bonding, thermal bonding) and/or gluing.

According to an embodiment of the present disclosure, the preparation method for the white LED chip described above comprises the following steps:
(a) bonding the non-light-emitting surface of the fluorescent transparent ceramic layer to the single crystal substrate through the bonding layer; or bonding the non-light-emitting surface of the fluorescent crystal layer to the single crystal substrate through the bonding layer;
(b) enabling an epitaxial structure to grow based on the other side of the single crystal substrate, wherein the epitaxial structure comprises: an N-type epitaxial layer, an emissive layer and a P-type epitaxial layer;
(c) manufacturing the LED chip wafer comprising at least one LED chip with a flip-chip or vertical structure on the epitaxial structure to obtain the white LED chip.

According to an embodiment of the present disclosure, the fluorescent transparent ceramic layer, the fluorescent crystal layer and the single crystal substrate have the meanings as described above.

According to an embodiment of the present disclosure, in step (a), the bonding layer has the meaning as described above.

According to an embodiment of the present disclosure, the preparation method for the white LED chip described above comprises the following steps:
(i) enabling the buffer layer to grow on the non-light-emitting surface of the fluorescent transparent ceramic layer by chemical vapor deposition (CVD) and other modes; or enabling the buffer layer to grow on the non-light-emitting surface of the fluorescent crystal layer in chemical vapor deposition (CVD) and other modes;
(ii) further enabling an LED epitaxial structure to grow on the buffer layer, wherein the LED epitaxial structure comprises: an N-type epitaxial layer, an emissive layer and a P-type epitaxial layer;
(iii) manufacturing the LED chip wafer comprising at least one LED chip with a flip-chip or vertical structure on the epitaxial structure to obtain the white LED chip.

According to an embodiment of the present disclosure, the fluorescent transparent ceramic layer and the fluorescent crystal layer have the meanings as described above.

According to an embodiment of the present disclosure, in step (i), the buffer layer is a buffer layer that is deposited and grown on the non-light-emitting surface of the fluorescent crystal layer and is compatible with the epitaxial structure, preferably including but not limited to at least one of materials such as SiC, Si, SiO₂, In₂O₃, AlN, and AlₓGa_{y}N.

For example, when the bonding layer is a metal elementary substance layer, the process of bonding the fluorescent transparent ceramic layer to the single crystal substrate comprises: plating a metal elementary substance film (i.e., a metal elementary substance layer) on the non-light-emitting surface of the fluorescent transparent ceramic layer, heating the metal for melting, and cooling the melted metal to realize the metal bonding of the fluorescent transparent ceramic layer and the LED chip wafer. For example, the metal bonding has a heating temperature of 500-1300° C., preferably 600-800° C.

For example, when the bonding layer is a metal elementary substance layer, the process of bonding the fluorescent crystal layer to the single crystal substrate comprises: plating a metal elementary substance film (i.e., a metal elementary substance layer) on the non-light-emitting surface of the fluorescent crystal layer, heating the metal for melting, and cooling the melted metal to realize the metal bonding of the fluorescent crystal layer and the LED chip wafer. For example, the metal bonding has a heating temperature of 500-1300° C., preferably 600-800° C.

For example, when the bonding layer is a sintered interface layer, the process of bonding the fluorescent transparent ceramic layer to the single crystal substrate comprises: generating a covalent bond (i.e., thermal bonding) by heating the non-light-emitting surface of the fluorescent transparent ceramic layer and the light-emitting surface of the LED chip wafer to realize the bonding. For example, the thermal bonding has a temperature of 800-1900° C., preferably 900-1500° C.

For example, when the bonding layer is a sintered interface layer, the process of bonding the fluorescent crystal layer to the single crystal substrate comprises: generating a covalent bond (i.e., thermal bonding) by heating the non-light-emitting surface of the fluorescent crystal layer and the light-emitting surface of the LED chip wafer to realize the bonding of the fluorescent transparent ceramic layer and the single crystal substrate. For example, the thermal bonding has a temperature of 800-1900° C., preferably 900-1500° C.

For example, when the bonding layer is a gluing layer, the process of bonding the fluorescent transparent ceramic layer to the single crystal substrate comprises: bonding the non-light-emitting surface of the fluorescent transparent ceramic layer to the LED chip wafer by using epoxy resin or silica gel.

For example, when the bonding layer is a gluing layer, the process of bonding the fluorescent crystal layer to the single crystal substrate comprises: bonding the non-light-emitting surface of the fluorescent crystal layer to the LED chip wafer by using epoxy resin or silica gel.

For example, when the bonding layer is a ceramic bonding layer, the process of bonding the fluorescent transparent ceramic layer to the single crystal substrate comprises: heating a composite ceramic containing the fluorescent transparent ceramic layer and the ceramic bonding layer to generate a covalent bond (i.e., thermal bonding) among the composite ceramic and the single crystal substrate of the LED chip wafer so as to realize the bonding; wherein a material of the ceramic bonding layer is the same as a single crystal material in the single crystal substrate. The composite ceramic containing the fluorescent transparent ceramic layer and the ceramic bonding layer can be obtained by high-temperature sintering (tape casting, dry pressing and other forming methods). For example, the thermal bonding has a temperature of 800-1900° C., preferably 900-1500° C.

For example, when the bonding layer is a ceramic bonding layer, the process of bonding the fluorescent crystal layer to the single crystal substrate comprises: heating a composite material containing the fluorescent crystal layer and the ceramic bonding layer to generate a covalent bond (i.e., thermal bonding) among the composite material and the single crystal substrate of the LED chip wafer so as to realize the bonding; wherein a material of the ceramic bonding layer is the same as a single crystal material in the single crystal substrate. The composite material containing the fluorescent crystal layer and the ceramic bonding layer can be obtained by high-temperature sintering. For example, the thermal bonding has a temperature of 800-1900° C., preferably 900-1500° C.

According to an embodiment of the present disclosure, the epitaxial structures in step (1), step (b) and step (ii) may be prepared by methods known in the art.

The present disclosure further provides use of the white LED chip described above in the field of semiconductor illumination, preferably in a semiconductor illumination device, and more preferably in a white LED device.

The present disclosure further provides a semiconductor illumination device, which comprises the white LED chip.

Preferably, the semiconductor illumination device comprises the white LED chip, an electrode and a conductive substrate.

Preferably, the semiconductor illumination device is a white LED device.

The present disclosure further provides a preparation method for the white LED device described above, which comprises the following steps: packaging the white LED chip, the electrode and the conductive substrate through COB to obtain the white LED device.

According to an embodiment of the present disclosure, before packaging, the white LED chip wafer can be cut to form a flip-chip LED chip wafer with the required number of chips, and then the flip-chip LED chip wafer is packaged with the conductive substrate.

### Beneficial Effects of Present Disclosure

The present disclosure improves the defects of the existing LED packaging, and the novel packaging mode can realize real inorganic packaging, and compared with a fluorescent powder, an organic glue and the like, the fluorescent transparent ceramic and the fluorescent crystal have the advantages of good thermal stability and small light attenuation; the COB packaged chip has high density, and the same fluorescent transparent ceramic sheet and fluorescent crystal sheet improve the light color consistency of the corresponding LED light source; the flip-chip LED structure has high light-emitting efficiency and good heat dissipation, and is suitable for manufacturing LED lamps with high light efficiency and high power.

### BRIEF DESCRIPTION OF THE DRAWINGS

FIG. 1 is a photograph of a fluorescent transparent ceramic layer and a ceramic bonding layer in Example 1; and

FIG. 2 is a schematic diagram of a flip-chip LED packaged in an inorganic material in example 1.

Reference numerals are as follows: 1. electrode, 2. fluorescent transparent ceramic layer, 3. aluminum oxide ceramic bonding layer, 4. LED chip wafer, and 5. conductive substrate.

### DETAILED DESCRIPTION

The technical scheme of the present disclosure will be further illustrated in detail with reference to the following specific examples. It should be understood that the following examples are merely exemplary illustration and explanation of the present disclosure, and should not be construed as limiting the protection scope of the present disclosure. All techniques implemented based on the content of the present disclosure described above are encompassed within the protection scope of the present disclosure.

Unless otherwise stated, the starting materials and reagents used in the following examples are all commercially available products or can be prepared using known methods.

### EXAMPLE 1

Step 1: enabling an epitaxial structure to grow based on a sapphire (aluminum oxide) single crystal substrate, wherein the epitaxial structure comprises an N-type epitaxial layer, an emissive layer and a P-type epitaxial layer.

Step 2: manufacturing a wafer comprising a plurality of LED chips with a flip-chip structure on the epitaxial structure.

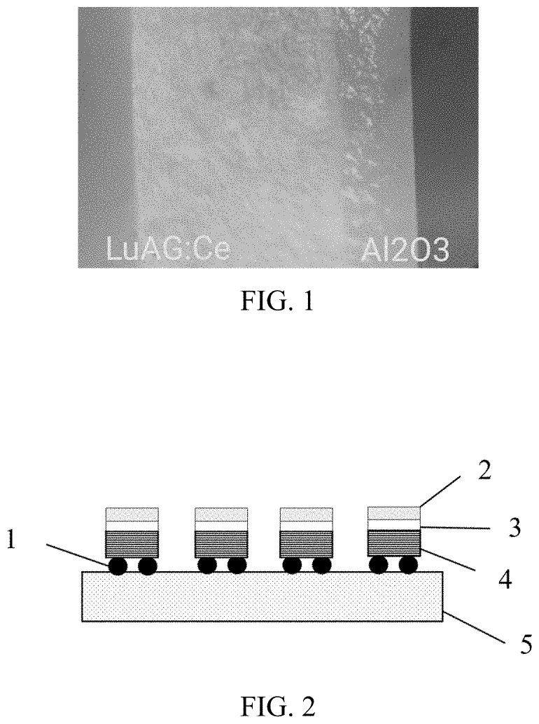

Step 3: manufacturing the fluorescent transparent ceramic layer 2 containing YAG:Ce, Mn and the aluminum oxide ceramic bonding layer 3 (see FIG. 1) with the same size as the chip wafer by adopting a tape casting method, wherein the aluminum oxide transparent ceramic bonding layer and the light-emitting surface of the sapphire single crystal substrate are both made of Al₂O₃ material, and realizing bonding by adopting the thermal bonding mode of generating a covalent bond Al—O layer, wherein the thermal bonding has a temperature of about 1300° C., and at this time, the white LED chip is sequentially provided with the LED chip wafer and an inorganic packaging material layer from bottom to top (see FIG. 2).

Step 4: cutting the white LED chip wafer packaged in the inorganic material described above to form the flip-chip LED chip wafer 4 with the required number of chips, and packaging the flip-chip LED chip wafer with the electrode 1 and the conductive substrate 5 by COB to obtain the white LED device.

According to the LED device in the example described above, an integrating sphere system is adopted for testing, the luminous efficiency of a light source exceeds 180 lm/W, and compared with a conventional flip-chip chip disclosed in CN201510900839.5 (about 150 lm/W), the luminous efficiency of the LED device disclosed by the present disclosure is significantly improved.

### EXAMPLE 2

Step 1: manufacturing a YAG:Ce fluorescent transparent ceramic sheet with a certain size, and bonding the YAG:Ce fluorescent transparent ceramic sheet with a sapphire single crystal substrate in an Aurum (Au) elementary substance layer metal bonding mode, wherein the metal bonding has a temperature of 700° C.

Step 2: taking the other surface of the sapphire single crystal substrate as a substrate, and enabling an epitaxial structure to grow on the substrate, wherein the epitaxial structure comprises a P-type epitaxial layer, an N-type epitaxial layer and an emissive layer.

Step 3: manufacturing a wafer comprising a plurality of LED chips with a flip-chip structure on the epitaxial structure, wherein at this time, the white LED chip is provided with the LED chip wafer and the fluorescent transparent ceramic sheet from bottom to top.

Step 4: cutting the white LED chip wafer packaged in the inorganic material described above to form the flip-chip LED chip wafer with the required number of chips, and packaging the flip-chip LED chip wafer with the conductive substrate by COB to obtain the white LED device.

According to the LED device in the example described above, an integrating sphere system is adopted for testing, the luminous efficiency of a light source exceeds 185 lm/W, and compared with a conventional flip-chip chip disclosed in CN201510900839.5 (about 150 lm/W), the luminous efficiency of the LED device disclosed by the present disclosure is significantly improved.

### EXAMPLE 3

Step 1: enabling an epitaxial structure to grow based on a sapphire single crystal substrate, wherein the epitaxial structure comprises an N-type epitaxial layer, an emissive layer and a P-type epitaxial layer.

Step 2: manufacturing a wafer comprising a plurality of LED chips with a flip-chip structure on the epitaxial structure.

Step 3: manufacturing a fluorescent transparent ceramic bonding layer containing LuAG:Ce with the same size as the chip wafer, and realizing the bonding by adopting an Argentum Ag elementary substance layer metal bonding mode, wherein the metal bonding has a temperature of 600° C.

Step 4: cutting the white LED chip wafer packaged in the inorganic material described above to form the flip-chip LED chip wafer with the required number of chips, and packaging the flip-chip LED chip wafer with the conductive substrate by COB to obtain the white LED device.

According to the LED device in the example described above, an integrating sphere system is adopted for testing, the luminous efficiency of a light source exceeds 195 lm/W, and compared with a conventional flip-chip chip disclosed in CN201510900839.5 (about 150 lm/W), the luminous efficiency of the LED device disclosed by the present disclosure is significantly improved.

### EXAMPLE 4

Step 1: enabling an epitaxial structure to grow based on a sapphire single crystal substrate, wherein the epitaxial structure comprises an N-type epitaxial layer, an emissive layer and a P-type epitaxial layer.

Step 2: manufacturing a wafer comprising a plurality of LED chips with a flip-chip structure on the epitaxial structure.

Step 3: manufacturing a fluorescent transparent ceramic bonding layer containing LuAG:Ce with the same size as the chip wafer, and realizing the bonding by adopting a silica gel gluing layer mode, wherein the bonding layer has a thickness of 0.5 μm.

Step 4: cutting the white LED chip wafer packaged in the inorganic material described above to form the flip-chip LED chip wafer with the required number of chips, and packaging the flip-chip LED chip wafer with the conductive substrate by COB to obtain the white LED device.

According to the LED device in the example described above, an integrating sphere system is adopted for testing, the luminous efficiency of a light source exceeds 180 lm/W, and compared with a conventional flip-chip chip disclosed in CN201510900839.5 (about 150 lm/W), the luminous efficiency of the LED device disclosed by the present disclosure is significantly improved.

### EXAMPLE 5

Step 1: enabling an epitaxial structure to grow based on a sapphire single crystal substrate, wherein the epitaxial structure comprises an N-type epitaxial layer, an emissive layer and a P-type epitaxial layer.

Step 2: manufacturing a wafer comprising a plurality of LED chips with a flip-chip structure on the epitaxial structure.

Step 3: manufacturing a fluorescent transparent ceramic bonding layer containing YAG:Ce with the same size as the chip wafer, and realizing the bonding by adopting the thermal bonding mode of generating a covalent bond Y-O layer, wherein the thermal bonding has a temperature of 1500° C.

Step 4: cutting the white LED chip wafer packaged in the inorganic material described above to form the flip-chip LED chip wafer with the required number of chips, and packaging the flip-chip LED chip wafer with the conductive substrate by COB to obtain the white LED device.

According to the LED device in the example described above, an integrating sphere system is adopted for testing, the luminous efficiency of a light source exceeds 175 lm/W, and compared with a conventional flip-chip chip disclosed in CN201510900839.5 (about 150 lm/W), the luminous efficiency of the LED device disclosed by the present disclosure is significantly improved.

### EXAMPLE 6

Step 1: manufacturing a YAG:Ce fluorescent single crystal sheet with a certain size, and bonding the YAG:Ce fluorescent single crystal sheet with a sapphire single crystal substrate in an indium (In) elementary substance layer metal bonding mode, wherein the metal bonding has a temperature of 500° C.

Step 2: taking the other surface of the sapphire single crystal substrate as a substrate, and enabling an epitaxial structure to grow on the substrate, wherein the epitaxial structure comprises a P-type epitaxial layer, an N-type epitaxial layer and an emissive layer.

Step 3: manufacturing a wafer comprising a plurality of LED chips with a vertical structure on the epitaxial structure, wherein at this time, the white LED chip is provided with the LED chip wafer and the fluorescent crystal sheet from bottom to top.

Step 4: cutting the white LED chip wafer packaged in the inorganic material described above to form the LED chip wafer in a vertical structure and with the required number of chips, and packaging the flip-chip LED chip wafer with the conductive substrate by COB to obtain the white LED device.

According to the LED device in the example described above, an integrating sphere system is adopted for testing, the luminous efficiency of a light source exceeds 180 lm/W, and compared with a conventional a chip with a vertical structure disclosed in doctoral dissertation of Wang Liancheng (Institute of Semiconductors, Chinese Academy of Sciences) (about 150 lm/W), the luminous efficiency of the LED device disclosed by the present disclosure is significantly improved.

### EXAMPLE 7

Step 1: manufacturing a YAG:Ce fluorescent crystal sheet with a certain size, and bonding the YAG:Ce fluorescent crystal sheet with a sapphire single crystal substrate by adopting an Aurum (Au) elementary substance layer metal bonding mode, wherein the metal bonding has a temperature of 700° C.

Step 2: taking the other surface of the sapphire single crystal substrate as a substrate, and enabling an epitaxial structure to grow on the substrate, wherein the epitaxial structure comprises a P-type epitaxial layer, an N-type epitaxial layer and an emissive layer.

Step 3: manufacturing a wafer comprising a plurality of LED chips with a flip-chip structure on the epitaxial structure, wherein at this time, the white LED chip is provided with the LED chip wafer and the fluorescent crystal sheet from bottom to top.

Step 4: cutting the white LED chip wafer packaged in the inorganic material described above to form the flip-chip LED chip wafer with the required number of chips, and packaging the flip-chip LED chip wafer with the conductive substrate by COB to obtain the white LED device.

According to the LED device in the example described above, an integrating sphere system is adopted for testing, the luminous efficiency of a light source exceeds 186 lm/W, and compared with a conventional flip-chip chip disclosed in CN201510900839.5 (about 150 lm/W), the luminous efficiency of the LED device disclosed by the present disclosure is significantly improved.

### EXAMPLE 8

Step 1: manufacturing a YAG:Ce fluorescent crystal sheet with a certain size.

Step 2: enabling SiC, MN and AlₓGa_{y}N materials to sequentially grow on a non-light-emitting surface of the fluorescent crystal sheet by a chemical vapor deposition (CVD) so as to form a buffer layer.

Step 3: further enabling an LED epitaxial structure to grow on the buffer layer, wherein the LED epitaxial structure comprises: an N-type epitaxial layer, an emissive layer and a P-type epitaxial layer.

Step 4: manufacturing a wafer comprising a plurality of LED chips with a flip-chip structure on the epitaxial structure, wherein at this time, the white LED chip is provided with the LED chip wafer and the fluorescent crystal sheet from bottom to top.

Step 5: cutting the white LED chip wafer packaged in the inorganic material described above to form an LED chip wafer with a flip-chip structure and with the required number of chips, and packaging the flip-chip LED chip wafer with the conductive substrate by COB to obtain the white LED device.

According to the LED device in the example described above, an integrating sphere system is adopted for testing, the luminous efficiency of a light source exceeds 190 lm/W, and compared with a conventional flip-chip chip disclosed in CN201510900839.5 (about 150 lm/W), the luminous efficiency of the LED device disclosed by the present disclosure is significantly improved.

The embodiments of the present disclosure have been described above. However, the present disclosure is not limited to the embodiments described above. Any modification, equivalent, improvement and the like made without departing from the spirit and principle of the present disclosure shall fall within the protection scope of the present disclosure.

1. A white LED chip, wherein the white LED chip comprises: an LED chip wafer and an inorganic material packaging layer, and the white LED chip further comprises a single crystal substrate;
the LED chip wafer at least comprises an LED chip with a flip-chip or vertical structure;
the inorganic material packaging layer is configured to package the LED chip wafer, and the inorganic material packaging layer comprises a fluorescent transparent ceramic sheet or a fluorescent crystal sheet.

2. The white LED chip according to claim 1, wherein the single crystal substrate is a sapphire (aluminum oxide) substrate, a silicon carbide substrate or a gallium nitride substrate;
preferably, the inorganic material packaging layer comprises a fluorescent transparent ceramic layer and a bonding layer;
preferably, the inorganic material packaging layer comprises a fluorescent crystal layer and a bonding layer;
preferably, a material of the fluorescent transparent ceramic layer includes but is not limited to a fluorescent transparent ceramic based on YAG and the like, preferably a YAG-based fluorescent transparent ceramic;
preferably, a material of the fluorescent crystal layer includes but is not limited to a fluorescent crystal based on YAG and the like, preferably a YAG-based fluorescent crystal;
preferably, the bonding layer includes but is not limited to at least one of a metal elementary substance layer, a sintered interface layer, a gluing layer, a ceramic bonding layer and a buffer layer;
preferably, the fluorescent transparent ceramic layer or the fluorescent crystal layer is a light-emitting surface of the inorganic material packaging layer;
preferably, in the white LED chip described above, a material of the ceramic bonding layer is the same as or different from, preferably the same as, a single crystal material of the single crystal substrate;
preferably, in the white LED chip described above, a material of the fluorescent crystal layer is the same as or different from, preferably the same as, a single crystal material of the single crystal substrate.

3. The white LED chip according to claim 1, wherein the inorganic material packaging layer is composed of a fluorescent transparent ceramic layer and a bonding layer, or the inorganic material packaging layer is composed of a fluorescent crystal layer and a bonding layer; preferably, a non-light-emitting surface of the fluorescent transparent ceramic layer is bonded to the bonding layer; preferably, a non-light-emitting surface of the fluorescent crystal layer is bonded to the bonding layer;
preferably, the bonding layer is a metal elementary substance layer, that is, a metal elementary substance layer is arranged between the non-light-emitting surface of the fluorescent transparent ceramic layer and the LED chip wafer, and the fluorescent transparent ceramic layer is bonded to the LED chip wafer through metal bonding; preferably, the bonding layer is a metal elementary substance layer, that is, a metal elementary substance layer is arranged between the non-light-emitting surface of the fluorescent crystal layer and the LED chip wafer, and the fluorescent crystal layer is bonded to the LED chip wafer through metal bonding; preferably, the metal elementary substance includes but is not limited to at least one of Au, Ag, In, Sn, Pb and the like;
preferably, the bonding layer is a gluing layer, that is, a gluing layer is arranged between the non-light-emitting surface of the fluorescent transparent ceramic layer and the LED chip wafer, and the fluorescent transparent ceramic layer is bonded to the LED chip wafer through gluing; preferably, the bonding layer is a gluing layer, that is, a gluing layer is arranged between the non-light-emitting surface of the fluorescent crystal layer and the LED chip wafer, and the fluorescent crystal layer is bonded to the LED chip wafer through gluing;
preferably, the bonding layer is a sintered interface layer, that is, a sintered interface layer is arranged between the non-light-emitting surface of the fluorescent transparent ceramic layer and the LED chip wafer, and the sintered interface layer is formed by heating, so that thermal bonding between the fluorescent transparent ceramic layer and the LED chip wafer is realized; preferably, the bonding layer is a sintered interface layer, that is, a sintered interface layer is arranged between the non-light-emitting surface of the fluorescent crystal layer and the LED chip wafer, and the sintered interface layer is formed by heating, so that thermal bonding between the fluorescent crystal layer and the LED chip wafer is realized; wherein a main component of the sintered interface layer is an inorganic compound, for example, the inorganic compound contains at least one of elements such as Al, Y, Si, Ga, O and N, and at least one of covalent bonds including but not limited to Al—O, Y—O, Si—O, Ga—N and Al—N exists among the elements;
preferably, the bonding layer comprises a ceramic bonding layer and a sintered interface layer, that is, a ceramic bonding layer and a sintered interface layer are arranged between the non-light-emitting surface of the fluorescent transparent ceramic layer and the LED chip wafer, and a material of the ceramic bonding layer is the same as a single crystal material of the single crystal substrate in the LED chip wafer; covalent bonds among the fluorescent transparent ceramic layer, the ceramic bonding layer and the single crystal substrate of the LED chip wafer are generated by heating to realize bonding;
preferably, the bonding layer comprises a fluorescent crystal layer and a sintered interface layer, that is, a ceramic bonding layer and a sintered interface layer are arranged between the non-light-emitting surface of the fluorescent crystal layer and the LED chip wafer, and a material of the ceramic bonding layer is the same as a single crystal material of the single crystal substrate in the LED chip wafer; covalent bonds among the fluorescent crystal layer, the ceramic bonding layer and the single crystal substrate of the LED chip wafer are generated by heating to realize bonding;
preferably, the bonding layer is a buffer layer, that is, a buffer layer is arranged between the non-light-emitting surface of the fluorescent transparent ceramic layer and the LED chip wafer, and then an LED epitaxial structure is further grown on the buffer layer, so as to manufacture a wafer with a plurality of LED chips and in a flip-chip or vertical structure; preferably, the buffer layer is a buffer layer that is deposited and grown on the non-light-emitting surface of the fluorescent transparent ceramic layer and is compatible with the epitaxial structure, preferably including but not limited to at least one of materials such as SiC, Si, SiO₂, In₂O₃, AlN, and AlₓGa_{y}N;
preferably, the bonding layer is a buffer layer, that is, a buffer layer is arranged between the non-light-emitting surface of the fluorescent crystal layer and the LED chip wafer, and then an LED epitaxial structure is further grown on the buffer layer, so as to manufacture a wafer with a plurality of LED chips and in a flip-chip or vertical structure; preferably, the buffer layer is a buffer layer that is deposited and grown on the non-light-emitting surface of the fluorescent crystal layer and is compatible with the epitaxial structure, preferably including but not limited to at least one of materials such as SiC, Si, SiO₂, In₂O₃, AlN, and AlₓGa_{y}N.

4. The white LED chip according to claim 1, wherein the LED chip comprises an N-type epitaxial layer, an emissive layer and a P-type epitaxial layer;
preferably, the LED chip is arranged on a non-light-emitting surface of the single crystal substrate or a non-light-emitting surface of the inorganic material packaging layer;
preferably, the LED chip wafer comprises one, two, three or more LED chips with flip-chip or vertical structures;
preferably, the fluorescent transparent ceramic has a light transmittance of 5%-85%.

5. The white LED chip according to claim 1, wherein
the white LED chip comprises: an LED chip wafer, an inorganic material packaging layer and a single crystal substrate;
the LED chip wafer comprises at least one LED chip with a flip-chip or vertical structure;
the inorganic material packaging layer is configured to package the LED chip wafer and composed of a fluorescent transparent ceramic layer and a bonding layer, or a fluorescent crystal layer and a bonding layer, a material of the fluorescent transparent ceramic layer includes but is not limited to a fluorescent transparent ceramic based on YAG and the like, a material of the fluorescent crystal layer includes but is not limited to a fluorescent crystal based on YAG and the like, and the bonding layer includes but is not limited to at least one of a metal elementary substance layer, a sintered interface layer, a gluing layer and a ceramic bonding layer;
the single crystal substrate is a sapphire (aluminum oxide) substrate, a silicon carbide substrate or a gallium nitride substrate;
a material of the ceramic bonding layer is the same as a single crystal material in the single crystal substrate.

6. The white LED chip according to claim 1, wherein
the white LED chip comprises: an LED chip wafer and an inorganic material packaging layer;
the LED chip wafer comprises at least one LED chip with a flip-chip or vertical structure;
the inorganic material packaging layer is configured to package the LED chip wafer and composed of a fluorescent transparent ceramic layer and a bonding layer, or a fluorescent crystal layer and a bonding layer, a material of the fluorescent transparent ceramic layer includes but is not limited to a fluorescent transparent ceramic based on YAG and the like, a material of the fluorescent crystal layer includes but is not limited to a fluorescent crystal based on YAG and the like, and the bonding layer includes but is not limited to at least one of a metal elementary substance layer, a sintered interface layer, a gluing layer and a buffer layer;
preferably, at least one of the metal elementary substance layer, the sintered interface layer, the gluing layer and the buffer layer is arranged between the non-light-emitting surface of the fluorescent transparent ceramic layer and the LED chip wafer, so that the fluorescent transparent ceramic sheet is bonded to the LED chip wafer;
or, at least one of the metal elementary substance layer, the sintered interface layer, the gluing layer and the buffer layer is arranged between the non-light-emitting surface of the fluorescent crystal layer and the LED chip wafer, so that the fluorescent crystal layer is bonded to the LED chip wafer.

7. A preparation method for the white LED chip according to claim 1, wherein the preparation method comprises the following steps: packaging the LED chip wafer by using the inorganic material packaging layer comprising the fluorescent transparent ceramic layer or the fluorescent crystal layer;
preferably, the preparation method for the white LED chip comprises the following steps:
(1) enabling an epitaxial structure to grow based on the single crystal substrate, wherein the epitaxial structure comprises: an N-type epitaxial layer, an emissive layer and a P-type epitaxial layer;
(2) manufacturing the LED chip wafer comprising at least one LED chip with a flip-chip or vertical structure on the epitaxial structure;
(3) packaging the LED chip wafer by using the fluorescent transparent ceramic layer and the bonding layer, wherein the fluorescent transparent ceramic layer is used as a light-emitting surface;
or packaging the LED chip wafer by using the fluorescent crystal layer and the bonding layer, wherein the fluorescent crystal layer is used as a light-emitting surface;
preferably, the preparation method for the white LED chip comprises the following steps:
(a) bonding the non-light-emitting surface of the fluorescent transparent ceramic layer to the single crystal substrate through the bonding layer; or bonding the non-light-emitting surface of the fluorescent crystal layer to the single crystal substrate through the bonding layer;
(b) enabling an epitaxial structure to grow based on the other side of the single crystal substrate, wherein the epitaxial structure comprises: an N-type epitaxial layer, an emissive layer and a P-type epitaxial layer;
(c) manufacturing the LED chip wafer comprising at least one LED chip with a flip-chip or vertical structure on the epitaxial structure to obtain the white LED chip;
preferably, the preparation method for the white LED chip comprises the following steps:
(i) enabling the buffer layer to grow on the non-light-emitting surface of the fluorescent transparent ceramic layer; or enabling the buffer layer to grow on the non-light-emitting surface of the fluorescent crystal layer;
(ii) further enabling an LED epitaxial structure to grow on the buffer layer, wherein the LED epitaxial structure comprises: an N-type epitaxial layer, an emissive layer and a P-type epitaxial layer;
(iii) manufacturing the LED chip wafer comprising at least one LED chip with a flip-chip or vertical structure on the epitaxial structure to obtain the white LED chip;
preferably, the buffer layer is a buffer layer that is deposited and grown on the non-light-emitting surface of the fluorescent crystal layer and is compatible with the epitaxial structure, preferably including but not limited to at least one of materials such as SiC, Si, SiO₂, In₂O₃, AlN, and AlₓGa_{y}N.

8. Use of the white LED chip according to claim 1 in the field of semiconductor illumination, preferably in a semiconductor illumination device, and more preferably in a white LED device.

9. A semiconductor illumination device, wherein the semiconductor illumination device comprises the white LED chip according to claim 1;
preferably, the semiconductor illumination device comprises the white LED chip according to claim 1 and a conductive substrate;
preferably, the semiconductor illumination device is a white LED device.

10. The preparation method for the white LED device according to claim 9, wherein the preparation method comprises the following steps: packaging the white LED chip and the conductive substrate through COB to obtain the white LED device.
